(19) United States
(12) Patent Application Publication
(10) Pub. No.: US 2006/0209942 A1
(43) Pub. Date: Sep. 21, 2006

(54) Higher-phase noise measurement method using frequency prescaler, an apparatus and a program using the method

(75) Inventors: Katsumi Onuma, Kanagawa (JP); Ashi Otsuya, Tokyo (JP)

Correspondence Address: Paul D. Greeley;Ohlandt, Greeley, Ruggiero & Perle, L.L.P., One Landmark Square, 10th Floor, Stamford, CT, 06901-2682, US

(73) Assignee: Agilent Technologies, Inc.

(21) Appl. No.: 11/347,347

(22) Filed: Feb. 3, 2006

(30) Foreign Application Priority Data
Mar. 17, 2005 (JP) 2005-077920

(51) Int. Cl. H04B 3/46; H03D 3/24

(52) U.S. Cl. 375/226; 375/375; 375/376

(57) ABSTRACT

Signals under test are subjected to frequency division before being input to a phase detector by a method for measuring the phase noise of signals under test using an apparatus for measuring phase noise comprising a phase detector. Moreover, the level of the output of the phase detector is multiplied by N times, or the level of the results of spectrum analysis of the output of the phase detector is collectively multiplied by N times, with N being the ratio of frequency division.

### 1. FIELD OF THE INVENTION

The present invention relates to technology for measuring phase noise and in particular, to technology for measuring high-level phase noise. It should be noted that high-level phase noise means phase noise that saturates a phase detector for measuring phase noise.

### 2. DISCUSSION OF THE BACKGROUND ART

Phase noise measurement is generally conducted by detecting the phase of input signals with a phase detector and a spectrum analysis of the output signals of the phase detector (for instance, refer to JP (Kokai) 4[1992]-350,576 (page 2, FIG. 4)). When the phase noise of signals to be input to a phase detector is very high, the wave detector becomes saturated and the measurements of phase noise are inaccurate. There is technology for inhibiting this type of saturation with which the phase of input signals is detected by a PLL circuit comprising a phase detector and a reference signal source (for instance, refer to JP (Kokai) 2003-287,555 (page 2, FIG. 4)). By means of this technology, the noise (phase difference between input signals) that is introduced to the phase detector is artificially controlled; therefore, saturation of the phase detector is inhibited.

However, phase detection technology using this PLL circuit cannot inhibit the saturation of a phase detector that is attributed to phase noise outside the loop band of the PLL circuit. Furthermore, a PLL has not been created for inverting the polarity of the output of the phase detector when the phase noise outside the loop band of the PLL circuit exceeds a predetermined level and there are cases where measurement is impossible. Many centimeter-wave bands and millimeter-wave band oscillators have such a high phase noise level that the above-mentioned saturation occurs and measurement is impossible. The phase conventional apparatuses for measuring phase noise. On the other hand, there has been a tendency toward an increase in communications using centimeter-wave bands and millimeter-wave bands, and there is a need for technology for measuring phase noise of centimeter-wave bands or millimeter-wave band signals.

### SUMMARY OF THE INVENTION

A method for measuring the phase noise of a signal under test using a phase detector, characterized in that it comprises a step for subjecting the signal under test to frequency division before the signal is input to the phase detector in order to prevent saturation of the phase detector inside the apparatus for measuring phase noise and to make it possible for the apparatus for measuring phase noise to measure the phase noise of a higher level than in the past.

Further characterized in that it comprises a step for multiplying N times the phase noise level of the signal under test measured by the apparatus for measuring phase noise with N being the ratio of the frequency division.

The method also comprises a step whereby the apparatus for measuring phase noise having the phase noise detector controls the frequency division ratio.

Another embodiment according to the present invention includes a measuring apparatus for measuring the phase noise of signals under test, characterized in that it has a frequency divider for frequency divisions of signals under test such that saturation of the phase detector inside the apparatus for measuring phase noise can be inhibited and the apparatus for measuring phase noise can measure phase noise of a higher level than in the past. This embodiment also comprises an arithmetic unit or amplifier for multiplying N times the phase noise level of measured signals under test with N being the frequency division ratio of the frequency divider. The measuring apparatus may also comprise a control device for controlling the ratio of the frequency divider.

Still a further embodiment includes a program that is executed by the apparatus for measuring phase noise, or the device for controlling the apparatus for measuring phase noise, characterized in that there is executed a step for multiplying by N times the phase noise level of signals under test that have been frequency divided by a ratio of N and measured by the apparatus for measuring phase noise.

The apparatus for measuring phase noise or the control device executes a step whereby the frequency division ratio of the frequency divider is controlled.

By means of the present invention, it is possible to measure signals having phase noise of a higher level than in the past. Moreover, there is no need for a frequency down converter for frequency conversion of signals under test so that they are within the frequency range at which the phase detector can operate. Thus, the cost of the entire measurement system is reduced.

### BRIEF DESCRIPTION OF THE DRAWINGS

FIG. 1 is a block diagram showing a system 10 for measuring phase noise that is the first embodiment of the present invention.

FIG. 2 is a block diagram showing phase detecting part 210.

FIG. 3 is a flow chart showing the operation of system 10 for measuring phase noise.

FIG. 4 is a graph showing the results of measuring phase noise.

FIG. 5 is a graph showing the results of measuring phase noise.

FIG. 6 is a block diagram showing a system 40 for measuring phase noise that is a revised example of system 10 for measuring phase noise.

### DETAILED DESCRIPTION OF THE PREFERRED EMBODIMENT

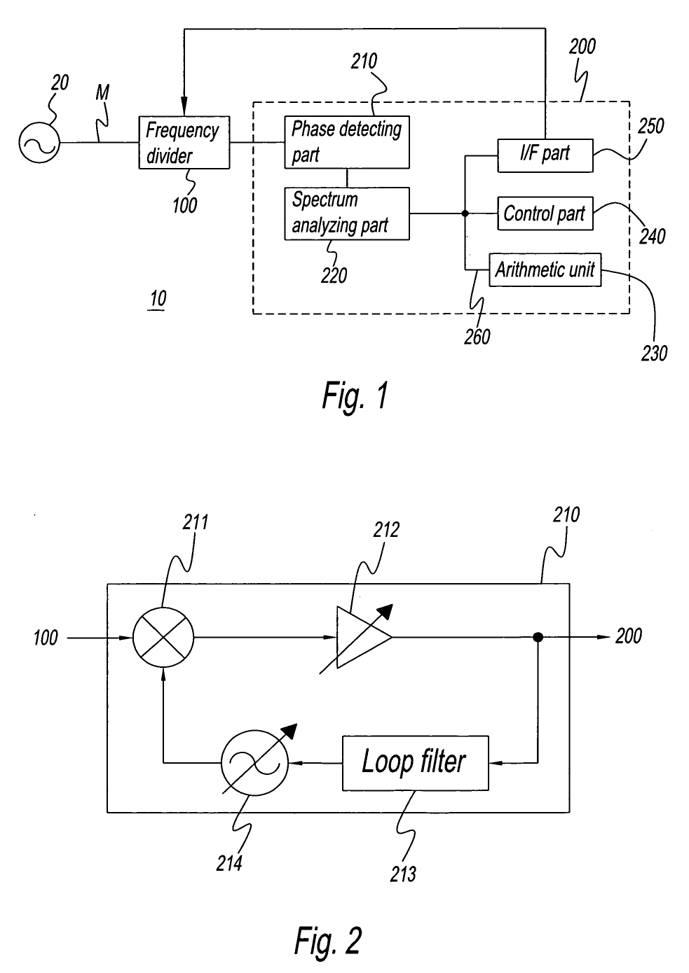

Embodiments of the present invention will now be described in detail while referring to the attached drawings. Refer to FIG. 1. FIG. 1 shows a block diagram of a system 10 for measuring phase noise that is the first embodiment of the present invention. System 10 for measuring phase noise in FIG. 1 comprises a frequency divider 100 and an apparatus 200 for measuring phase noise. Frequency divider 100 is a device for dividing the frequency of input signals by a predetermined ratio N. Frequency division ratio N can be controlled from the outside. The input of frequency divider 100 is connected to the output of a device 20 for generating signals under test M. Consequently, frequency divider 100 outputs with the frequency of signals under test M being 1/N. Apparatus 200 for measuring phase noise is an apparatus for measuring the phase noise of input signals. Apparatus 200 for measuring phase noise comprises a phase detecting part 210, a spectrum analyzing part 220, an arithmetic part 230, a control part 240, and an interface part 250. Apparatus 200 for measuring phase noise is connected to the output of the frequency divider 100 and measures the phase noise of the output signals of frequency divider 100. The interface part in FIG. 1 is called the I/F part.

Phase detecting part 210 is the device for detecting the phase of the input signals and outputting the detected phase signals. The input of phase detector 210 is connected to the output of frequency divider 100. Spectrum analyzing part 220 is the device that analyzes the spectrum of the input signals. The input of spectrum analyzing part 220 is connected to the output of phase detector 210. Arithmetic unit 230 is the device that processes the results of analysis by spectrum analyzing part 220. Control part 240 is the device that controls each of the structural elements inside apparatus 200 for measuring phase noise by executing a program. Spectrum analyzing part 220, arithmetic unit 230, and control part 240 are, for instance, a CPU, DSP, or another processor or computer. Interface part 250 is the input device for communicating outside of apparatus 200 for measuring phase noise. Interface part 250 is connected to frequency divider 100. Interface part 250 is, for instance, a liquid crystal display for displaying the measurement results to the operator, buttons for receiving instructions from the operator, or a LAN interface for communication with outside equipment. Spectrum analyzing part 220, arithmetic unit 230, control part 240, and interface part 250 are connected to one another via a bus 260. Bus 260 is used for control and data transmission.

Phase detecting part 210 has a PLL that uses a phase detector. The internal structure of phase detecting part 210 will be briefly discussed here.

Refer to FIG. 2. FIG. 2 is a block diagram of phase detecting part 210. Phase detecting part 210 in FIG. 2 comprises a phase detector 211, a variable gain amplifier 212, a loop filter 213, and an externally controlled oscillator 214. Phase detector 211 detects the phase difference between two input signals and outputs the difference as a phase signal. Phase detector 211 is generally a ring modulator-type. However, this does not mean that the phase detector is limited to this type. Phase detector 211 can be another type of phase detector; for instance, a vector synthesizing type, a switch type, or another analog phase detector, or a digital phase detector can also be used. Moreover, the externally controlled oscillator 214 is an oscillator that changes the frequency or phase of output signals in response to the output of the loop filter. The operating theory of phase detecting part 210 is well known and a detailed description is therefore not given.

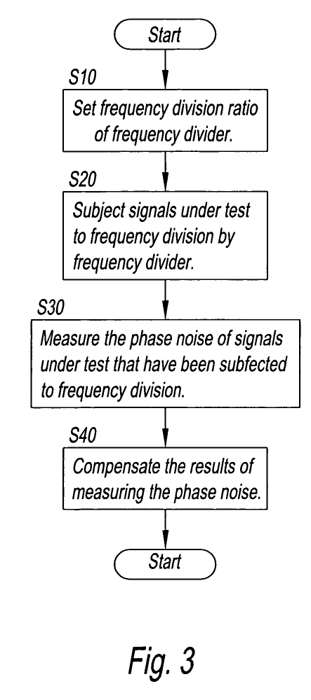

A description will now be given of the operation of system 10 for measuring phase noise constructed as described above. The operation of system 10 for measuring phase noise is controlled by control part 240. The necessary program is preloaded into control part 240. Control part 240 controls the operation of system 10 for measuring phase noise by executing this program. Refer to FIGS. 1 and 3. FIG. 3 is a flow chart showing the series of operations of system 10 for measuring phase noise.

First, the frequency division ratio of frequency divider 100 is set in step S10. Specifically, frequency control part 240 controls frequency divider 100 via interface part 250 and sets the frequency division ratio of frequency divider 100. The frequency division ratio N can be an integer or a decimal. Moreover, the frequency division ratio N is pre-input into apparatus 200 for measuring phase noise via interface part 250. This step is not necessary when the frequency division ratio of frequency divider 100 is fixed or when the ratio must be manually changed.

Next, the frequency of the signal under test M is divided by frequency divider 100 in step S20. The frequency of the signal under test M is thereby divided by a ratio of N and applied to apparatus 200 for measuring phase noise. The signal under test M that has been subjected to frequency division is signal under test Md here.

Next, in step 30, the phase noise of the signal under test Md is measured. Phase information of the signal under test Md is detected by phase detecting part 210. The detected phase information is applied to spectrum analyzing part 220 as phase signals. The spectrum of the input phase signals is analyzed at the spectrum analyzing part. The resulting spectrum represents the phase noise of the signal under test Md. The phase noise of the signal under test Md is Pd here. Spectrum analysis is performed by FFT processing. Moreover, the spectrum analysis is not limited to this method and can be accomplished by a spectrum analyzer that uses a sweeper, and similar devices.

Finally, the measured phase noise Pd is compensated in step S40. The phase noise Pd is 1/N the level of the phase noise P of the signal under test M. Therefore, compensation such that the level of phase noise Pd is multiplied N times is performed in order to obtain phase noise P. There are several methods for multiplying the level of phase noise Pd by N. For instance, arithmetic unit 230 obtained the results of measuring the phase noise Pd from spectrum analyzing part 220 and the level of the measured phase noised Pd is collectively multiplied N times. The results of measuring the phase noise Pd are generally plotted on a logarithmic graph in units of dB/Hz. Therefore, it is possible to add 20 log₁₀(N) to the level of the measurement results of the phase noise Pd displayed on the graph, or to change the indices of a scale that represents the level of the phase noise Pd. Another method for essentially multiplying N times the level of the phase noise Pd can also be used. It should be noted that the processing in this step is not necessary when it is unnecessary to perform level compensation, such as when only the waveform of the phase noise Pd is monitored, and in similar situations.

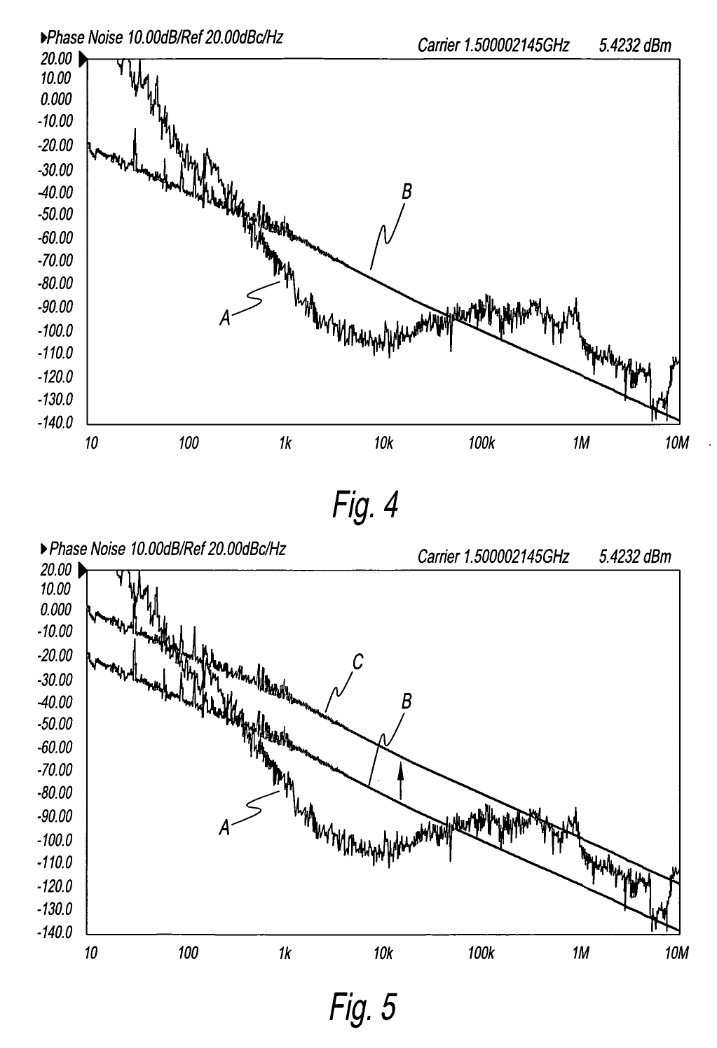

The results of the present invention will now be briefly described while referring to FIGS. 4 and 5. FIG. 4 shows the results A of measuring the phase noise P of the signal under test M by application of the signal under test M to apparatus 200 for measuring phase noise without performing frequency division and the results B of measuring the phase noise Pd by the system for measuring phase noise in FIG. 1. The signal under test M in this case has such high phase noise that phase detector 211 is saturated. As is clear from FIG. 4, the results A show a large undulation collectively and it is clear that they are the results that were incorrectly measured. On the other hand, results B collectively form a straight line with a gentle slope descending to the right and it is clear that they are results that were correctly measured. Refer to FIG. 5. FIG. 5 shows the results A and B in FIG. 4 as well as the results C obtained by compensation of the results B. Results C in FIG. 5 were obtained by compensating the results of measuring the phase noise of signals that were produced by dividing the frequency of the signal under test M by a ratio of 5. When the results are compared, the results C are the product of collective compensation of the phase noise level of the results B to 20 log 10(5)≈14 (dB).

It appears that the only uncertainty in the measurements added by frequency divider 100 is from white noise of frequency divider 100, and this can be estimated. For instance, this estimate is used to infer the noise level of the entire system 10 for measuring phase noise, that is, the lower limit of measurement. The noise level of system 10 for measuring phase noise apparently corresponds to apparatus 200 for measuring phase noise under a range within which there is no effect from the white noise of frequency divider 100.

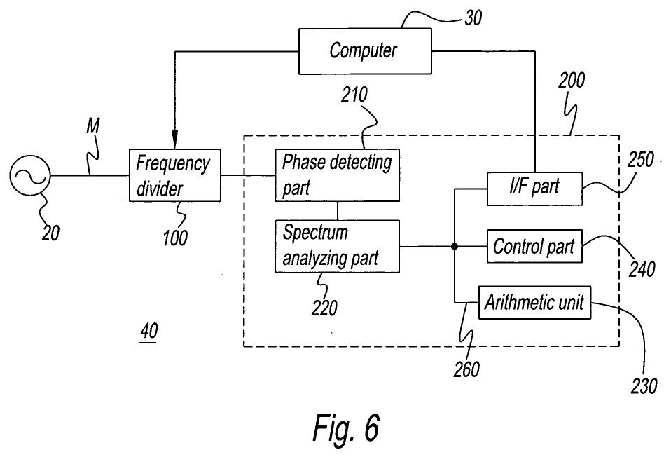

However, system 10 for measuring phase noise of the first embodiment uses apparatus 200 for measuring phase noise to set the frequency division ratio of frequency divider 100 and to compensate the phase noise level. However, the setting of the frequency division ratio and/or the level compensation can also be performed by an outside processor. An example is a system 40 for measuring phase noise shown in FIG. 6. System 40 for measuring phase noise has a computer 30 added to system 10 for measuring phase noise. Computer 30 communicates with each of the structural units of apparatus 200 for measuring phase noise through interface 250. Moreover, computer 30 sets the frequency division ratio of frequency divider 100 in place of apparatus 200 for measuring phase noise. Computer 30 compensates the level of the results of measuring the phase noise Pd in place of arithmetic unit 230.

Moreover, by means of the first embodiment, the output of phase detecting part 210 can be multiplied N times in order to multiply by N times the level of the phase noise Pd. The output of phase detecting part 210 is multiplied N times because it is the equivalent of collectively multiplying by N times the level of the phase noise Pd. In this case, the order of measurement of phase noise and level compensation is reversed. For example, the output of phase detecting part 210 is multiplied by N times by arithmetic part 230, and then the output is treated by spectrum analyzing part 220 to obtain the phase noise P. It is also possible to dispose a fixed-gain amplifier or a variable-gain amplifier between the output of phase detecting part 210 and the input of spectrum analyzing part 220. It should be possible to adjust the gain of the variable-gain amplifier in this case by control part 240.

However, in the first embodiment, the signal under test M is frequency divided; therefore, when apparatus 200 for measuring phase noise has a function corresponding to the frequency of the input signals, there is a possibility that the opposite of the original operation would be performed. In order to prevent this, apparatus 200 for measuring phase noise can compensate the frequency of the input signals. For instance, the frequency can be displayed after being multiplied N times when the frequency of the input signals is measured and displayed.

The present invention can be efficiently used as technology for avoiding the saturation of a phase detector, and the like, even when phase-modulated waves of signals under test are measured. In short, it is possible to multiply by N times the signals under test before the phase-modulated waves of the signals under test are detected by a phase detector. Moreover, if necessary, the output level of the phase detector can be multiplied N times so that the same signals as the original phase-modulated waves are obtained. An amplifier or arithmetic unit can be used for level compensation. Embodiments for measuring phase-modulated waves of signals under test are cited below. These embodiments can probably be more fully understood by referring to FIG. 1 and substituting apparatus 200 for measuring phase noise by the apparatus for measuring phase-modulated waves and spectrum analyzing part 220 by the part for measuring phase-modulated waves.

### Embodiment A

A method for measuring the phase-modulated waves of signals under test using a phase detector, the method being characterized in that it comprises a step for the frequency division of the signals under test before they are input to the phase detector.

### Embodiment B

The method cited in Embodiment A, further characterized in that it comprises a step for essentially multiplying by N times the level of the output of the phase detector where N is the ratio of frequency division.

### Embodiment C

A measuring apparatus for measuring the phase-modulated waves of signals under test, the measuring apparatus being characterized in that it comprises a frequency divider for the frequency division of the signals under test.

### Embodiment D

The measuring apparatus cited in Embodiment C, further characterized in that it comprises an arithmetic unit or amplifier for essentially multiplying by N times the output level of the phase detector that will measure with N being the frequency division ratio of the frequency divider.

### Embodiment E

A program that is executed by an apparatus for measuring phase-modulated waves or a device for controlling an apparatus for measuring phase-modulated waves, the program being characterized in that there is executed a step for essentially multiplying by N times the phase-modulated level of signals under test that have been N frequency divided as measured by the apparatus for measuring phase-modulated waves.

What is claimed is:

1. A method for measuring the phase noise of a signal under test using a phase detector, said method comprises subjecting the signal under test to frequency division before the signal is input to the phase detector.

2. The method according to claim 1, further comprising essentially multiplying by N times the level of the output of the phase detector or the level of the phase noise of the signal under test obtained from the output with N being the ratio of the frequency division.

3. A measuring apparatus for measuring the phase noise of a signal under test, said apparatus comprising a frequency divider for frequency division of the signals under test.

4. The measuring apparatus according to claim 3, further comprising an arithmetic unit or amplifier for essentially multiplying by N times the measured phase noise level of the signal under test with N being the ratio of frequency division of the frequency divider.

5. The measuring apparatus according to claim 3, further comprising an interface for controlling the frequency division ratio of the frequency divider.

6. A program to be executed by an apparatus for measuring phase noise or a device for controlling an apparatus for measuring phase noise, the program comprising executing a step whereby the phase noise level of a signal under test that has been frequency divided by N as measured by the apparatus for measuring phase noise is essentially multiplied by N times.

7. The program according to claim 6, further comprising controlling the frequency division ratio is further executed by the apparatus for measuring phase noise or the control device.
